(19) United States
(12) Patent Application Publication
(10) Pub. No.: US 2023/0420260 A1
(43) Pub. Date: Dec. 28, 2023

(54) POLISHING LIQUID COMPOSITION FOR SILICON OXIDE FILM

(71) Applicant: Kao Corporation, Tokyo (JP)

(72) Inventors: Masato SUGAHARA, Wakayama (JP); Norihito YAMAGUCHI, Wakayama (JP)

(73) Assignee: Kao Corporation, Tokyo (JP)

(21) Appl. No.: 18/039,111

(22) PCT Filed: Nov. 12, 2021
(86) PCT No.: PCT/JP2021/041685

§ 371 Date: May 26, 2023

(30) Foreign Application Priority Data
Nov. 27, 2020 (JP) 2020-197119
Oct. 25, 2021 (JP) 2021-173999

(51) Int. Cl. H01L 21/306; C09G 1/02; H01L 21/768

(52) U.S. Cl. CPC H01L 21/30625; C09G 1/02; H01L 21/7684

(57) ABSTRACT

In one aspect, provided is a polishing liquid composition for a silicon oxide film that is able to improve the polishing selectivity in the polishing of a silicon oxide film.

An aspect of the present disclosure relates to a polishing liquid composition for a silicon oxide film. The polishing liquid composition contains cerium oxide particles (component A), a water-soluble anionic condensate (component B), and an aqueous medium. The component B is a co-condensate of monomers including a monomer (constituent monomer b1) represented by the following formula (I) and a monomer (constituent monomer b2) represented by the following formula (II). A molar ratio (%) of the constituent monomer b1 to the total of the constituent monomer b1 and the constituent monomer b2 in the component B is more than 30%.

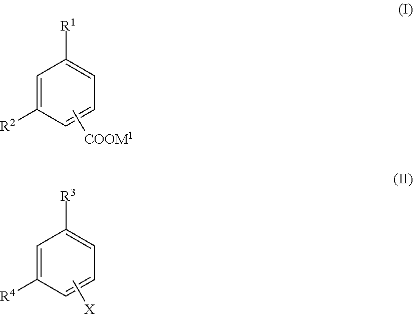

### TECHNICAL FIELD

The present disclosure relates to a polishing liquid composition that contains cerium oxide particles and is used for a silicon oxide film, a method for producing a semiconductor substrate by using the polishing liquid composition, and a method for polishing a substrate with the polishing liquid composition.

### BACKGROUND ART

Chemical mechanical polishing (CMP) is a planarization technique in which a working surface of a substrate to be polished is brought into contact with a polishing pad, and the substrate and the polishing pad are moved relative to each other while a polishing liquid is being supplied to the contact area between them, so that the raised and trench areas of the surface of the substrate undergo a chemical reaction and are removed mechanically.

At present, the CMP technique is essential for, e.g., the planarization of an interlayer insulation film, the formation of a shallow trench element isolation structure (also referred to as an “element isolation structure” in the following), or the formation of plugs and embedded metal wiring in the manufacturing process of semiconductor devices. The recent rapid progress in multilayer semiconductor devices with high definition has increased demand for high speed polishing as well as better flatness. For example, in the process of forming the shallow trench element isolation structure, it is desirable that not only the polishing rate, but also the polishing selectivity of a polishing stopper film (e.g., a silicon nitride film) with respect to a film to be polished (e.g., a silicon oxide film) be improved. In other words, the polishing selectivity indicates that the polishing stopper film is less likely to be polished than the film to be polished.

WO 99/43761A1 (Patent Document 1) discloses an abrasive composition for polishing a semiconductor device in a shallow trench isolation process. The abrasive composition contains water, cerium oxide powder, and one or more water-soluble organic compounds having at least one of a —COOH group, a —COOM_{X} group, a —SOH group, and a —SO₃M_{Y} group.

JP 2019-116520 A (Patent Document 2) discloses the use of a water-soluble co-condensate of monomers with phenol skeletons to polish a magnetic disk substrate. Patent Document 2 teaches that the ratio of 4-hydroxybenzoic acid is 20% in Example 11.

### DISCLOSURE OF INVENTION

An aspect of the present disclosure relates to a polishing liquid composition for a silicon oxide film. The polishing liquid composition contains cerium oxide particles (component A), a water-soluble anionic condensate (component B), and an aqueous medium.

The component B is a co-condensate of monomers including a monomer (constituent monomer b1) represented by the following formula (I) and a monomer (constituent monomer b2) represented by the following formula (II).

A molar ratio (%) of the constituent monomer b1 to the total of the constituent monomer b1 and the constituent monomer b2 in the component B is more than 30%.

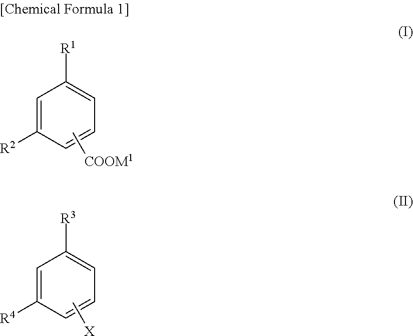

In the formula (I), R¹ and R² are the same or different and represent a hydrogen atom, a hydrocarbon group having 1 to 4 carbon atoms, or —OM², and M¹ and M² are the same or different and represent an alkali metal ion, an alkaline earth metal ion, an organic cation, ammonium (NH₄⁺), or a hydrogen atom.

In the formula (II), R³ and R⁴ are the same or different and represent a hydrogen atom, a hydrocarbon group having 1 to 4 carbon atoms, or —OM³, X represents —SO₃M⁴ or —PO₃M⁵M⁶, and M³, M⁴, M⁵, and M⁶ are the same or different and represent an alkali metal ion, an alkaline earth metal ion, an organic cation, ammonium (NH₄⁺), or a hydrogen atom.

An aspect of the present disclosure relates to a method for producing a semiconductor substrate. The method includes polishing a film to be polished with the polishing liquid composition of the present disclosure.

An aspect of the present disclosure relates to a polishing method. The polishing method includes polishing a film to be polished with the polishing liquid composition of the present disclosure. The film to be polished is a silicon oxide film that is formed in the process of producing a semiconductor substrate.

### Description of the Invention

In the field of semiconductor, wiring has been required to be finer and more complicated due to a high level of integration in recent years. This in turn requires that the polishing selectivity is improved while the polishing rate is maintained in the CMP process.

Moreover, the flatness of a substrate surface after polishing can be degraded. This problem may be attributed in part to dishing that occurs when polishing of a stopper film (silicon nitride film) cannot be successfully reduced after the stopper film is exposed by polishing.

The present disclosure provides a polishing liquid composition for a silicon oxide film that is able to improve the polishing selectivity in the polishing of a silicon oxide film, a method for producing a semiconductor substrate by using the polishing liquid composition, and a polishing method with the polishing liquid composition.

In another aspect, the present disclosure provides a polishing liquid composition for a silicon oxide film that is able to reduce the polishing rate of a silicon nitride film and to improve the flatness of a substrate surface after polishing by preventing dishing, a method for producing a semiconductor substrate by using the polishing liquid composition, and a polishing method with the polishing liquid composition.

In one aspect, the present disclosure can provide a polishing liquid composition for a silicon oxide film that is able to improve the polishing selectivity in the polishing of a silicon oxide film.

In one aspect, the present disclosure can provide a polishing liquid composition for a silicon oxide film that is able to reduce the polishing rate of a silicon nitride film and to improve the flatness of a substrate surface after polishing by preventing dishing.

The present inventors conducted intensive studies and made the findings that the combination of a polishing liquid composition containing cerium oxide (also referred to as “ceria” in the following) particles that serve as abrasive grains with a particular anionic condensate could improve the polishing selectivity in the polishing of a silicon oxide film.

Moreover, the present disclosure is based on the findings that the combination of the polishing liquid composition containing the ceria abrasive grains with the anionic condensate could reduce the polishing rate of a silicon nitride film and improve the flatness of a substrate surface after polishing by preventing dishing.

The details of the mechanism of the effects of the present disclosure are not fully clear, but can be considered as follows.

In order to improve the polishing selectivity, the polishing rate of a polishing stopper film needs to be reduced without significantly impairing the polishing rate of an object to be polished. The component B can efficiently form a protective film because the condensate itself has a rigid structure. The component B has a carboxylic acid group as well as a sulfonic acid group or a phosphonic acid group to ensure water solubility. The carboxylic acid group is present in an amount greater than the predetermined amount. Therefore, the component B in the polishing liquid composition can be selectively bound more strongly to a silicon nitride film than to a silicon oxide film. In other words, the component B can be selectively bound to the silicon nitride film to efficiently form a strong protective film. The formation of the protective film can reduce the polishing rate of the silicon nitride film, can improve the polishing selectivity, and can also prevent dishing, thereby improving the flatness of a substrate surface after polishing. The interaction of the component C with the component B can increase the strength of the protective film that is formed of the component B on the silicon nitride film. This can further improve the polishing selectivity, and can further prevent dishing, thereby improving the flatness of a substrate surface after polishing.

However, the present disclosure should not be interpreted solely by the above mechanism.

In one or more embodiments, the present disclosure relates to a polishing liquid composition for a silicon oxide film (also referred to as a “polishing liquid composition of the present disclosure” in the following). The polishing liquid composition of the present disclosure contains cerium oxide particles (component A), a water-soluble anionic condensate (component B), and an aqueous medium. The component B is a co-condensate of monomers including a monomer (constituent monomer b1) represented by the formula (I) and a monomer (constituent monomer b2) represented by the formula (II). A molar ratio (%) of the constituent monomer b1 to the total of the constituent monomer b1 and the constituent monomer b2 in the component B is more than 30%.

In the present disclosure, the “polishing selectivity” means the same as the ratio of the polishing rate of the film to be polished (e.g., the silicon oxide film) to the polishing rate of the polishing stopper film (e.g., the silicon nitride film) (polishing rate of film to be polished/polishing rate of polishing stopper film). The higher the “polishing selectivity,” the larger the ratio of polishing rate.

[Cerium Oxide Particles (Component A)]

The polishing liquid composition of the present disclosure contains cerium oxide (also referred to as “ceria” in the following) particles (also referred to simply as a “component A” in the following) as polishing abrasive grains. The component A may be either positively charged ceria or negatively charged ceria. The chargeability of the component A can be confirmed by measuring a potential (surface potential) on the surface of the abrasive grains with, e.g., an electroacoustic method, or an electrokinetic sonic amplitude (ESA)method. The surface potential can be measured with, e.g., “ZetaProbe” (manufactured by Kyowa Interface Science Co., Ltd.) and specifically by a method as described in Examples. The component A may be of one type or two or more different types.

The production method, shape, and surface state of the component Aare not limited. Examples of the component A include colloidal ceria, irregularly-shaped ceria, and ceria-coated silica.

The colloidal ceria can be obtained by a build-up process, e.g., in the method described in Examples 1 to 4 of JP2010-505735A

The irregularly-shaped ceria may be, e.g., crushed ceria. An embodiment of the crushed ceria may be, e.g., calcined and crushed ceria obtained by calcining and crushing cerium compounds such as cerium carbonate and cerium nitrate. Another embodiment of the crushed ceria may be, e.g., single crystal crushed ceria obtained by wet-crushing ceria particles in the presence of an inorganic acid or organic acid. The inorganic acid used in the wet-crushing process may be, e.g., a nitric acid. The organic acid used in the wet-crushing process may be, e.g., an organic acid having a carboxyl group. Specifically, the organic acid may be at least one selected from polycarboxylate such as ammonium polyacrylate, a picolinic acid, a glutamic acid, an aspartic acid, an aminobenzoic acid, and a p-hydroxybenzoic acid. For example, the positively charged ceria can be obtained by using at least one selected from a picolinic acid, a glutamic acid, an aspartic acid, an aminobenzoic acid, and a p-hydroxybenzoic acid in the wet-crushing process. The negatively charged ceria can be obtained by using polycarboxylate such as ammonium polyacrylate in the wet-crushing process. The wet-crushing process may be, e.g., wet-crushing with a planetary bead mill or the like.

The ceria-coated silica may be, e.g., composite particles obtained by covering at least a part of the surface of individual silica particles with granular ceria, e.g., with the method described in Examples 1 to 14 of JP2015-63451 A or Examples 1 to 4 of JP2013-119131 A The composite particles can be obtained by, e.g., deposition of ceria on the silica particles.

The component A may have, e.g., a substantially spherical shape, a polyhedral shape, or a raspberry-like shape.

The average primary particle size of the component A is preferably 5 nm or more, more preferably 10 nm or more, even more preferably 20 nm or more, and further preferably 30 nm or more from the viewpoint of improving the polishing rate and the flatness. Furthermore, the average primary particle size of the component A is preferably 300 nm or less, more preferably 200 nm or less, even more preferably 150 nm or less, still more preferably 100 nm or less, yet more preferably 80 nm or less, and further preferably 60 nm or less from the viewpoint of reducing the occurrence of polishing scratches. In the present disclosure, the average primary particle size of the component A is calculated by using a BET specific surface area S (m²/g) that is determined with a BET (nitrogen adsorption) method. The BET specific surface area can be measured by a method as described in Examples.

The content of the component Ain the polishing liquid composition of the present disclosure is preferably 0.001% by mass or more, more preferably 0.01% by mass or more, even more preferably 0.05% by mass or more, still more preferably 0.1% by mass or more, and further preferably 0.15% by mass or more from the viewpoint of improving the polishing rate and the flatness. Furthermore, the content of the component A is preferably 6% by mass or less, more preferably 3% by mass or less, even more preferably 1% by mass or less, and further preferably 0.7% by mass or less from the viewpoint of reducing the occurrence of polishing scratches. More specifically, the content of the component A is preferably 0.001% by mass or more and 6% by mass or less, more preferably 0.01% by mass or more and 6% by mass or less, even more preferably 0.05% by mass or more and 3% by mass or less, still more preferably 0.1% by mass or more and 1% by mass or less, and further preferably 0.15% by mass or more and 0.7% by mass or less. When the component A includes two or more types of ceria particles, the content of the component A is the total content of the two or more types of ceria particles.

[Water-Soluble Anionic Condensate (Component B)]

The polishing liquid composition of the present disclosure contains a water-soluble anionic condensate (also referred to simply as a “component B” in the following). The component B may be of one type or two or more different types. In the present disclosure, the term “water-soluble” means that the anionic condensate dissolves in the polishing liquid composition and has a solubility of preferably 0.5 g/100 mL or more, and more preferably 2 g/100 mL or more in water (at 20° C.).

In one or more embodiments the component B can serve to reduce the polishing rate of the silicon nitride film and improve the polishing selectivity. Moreover, in one or more embodiments, the component B can serve to reduce both the polishing rate of the silicon nitride film and the dishing rate during overpolishing, so that the flatness of a substrate surface after polishing can be improved. The “dishing” means a dish-like depression caused by excessive polishing of a film disposed in a trench area.

The component B is a co-condensate of monomers including a monomer (constituent monomer b1) represented by the following formula (I) and a monomer (constituent monomer b2) represented by the following formula (II). The component B may also be referred to as an anionic condensate having an aromatic ring in the main chain.

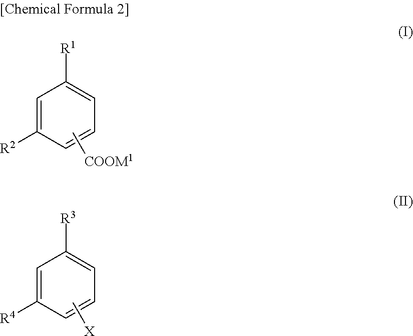

(Constituent Monomer b1)

The constituent monomer b1 is a monomer represented by the formula (I).

In the formula (I), R¹ and R² are the same or different and represent a hydrogen atom, a hydrocarbon group having 1 to 4 carbon atoms, or —OM². In one or more embodiments at least one of R¹ and R² is preferably —OM², and more preferably —OH from the viewpoint of the polymerization reactivity. In one or more embodiments, at least one of R¹ and R² is preferably a hydrogen atom from the viewpoint of improving the polishing selectivity and the flatness.

M¹ and M² are the same or different and represent an alkali metal ion, an alkaline earth metal ion, an organic cation, ammonium (NH₄⁺), or a hydrogen atom. In one or more embodiments, the organic cation may be an organic ammonium, including, e.g., alkylammonium such as tetramethylammonium, tetraethylammonium, and tetrabutylammonium.

In one or more embodiments, M¹ is preferably at least one selected from an alkali metal ion, ammonium (NH₄⁺), and a hydrogen atom, and more preferably at least one selected from a sodium ion, a potassium ion, ammonium (NH₄⁺), and a hydrogen atom from the viewpoint of improving the polishing selectivity and the flatness.

In one or more embodiments, M² is preferably at least one selected from an alkali metal ion, ammonium (NH₄⁺), and a hydrogen atom, more preferably at least one selected from a sodium ion, a potassium ion, ammonium (N₄⁺), and a hydrogen atom, and further preferably a hydrogen atom from the viewpoint of improving the polishing selectivity and the flatness.

In one or more embodiments the constituent monomer b1 is preferably a hydroxybenzoic acid (HBA) or a dihydroxybenzoic acid (DHBA), more preferably a 4-hydroxybenzoic acid (4-HBA), a 2-hydroxybenzoic acid (2-HBA), a 2,4-dihydroxybenzoic acid (2,4-HBA), or a 2,6-dihydroxybenzoic acid (2,6-HBA), and further preferably a 4-hydroxybenzoic acid (4-HBA) from the viewpoint of improving the polishing selectivity and the flatness.

(Constituent Monomer b2)

The constituent monomer b2 is a monomer represented by the formula (II).

In the formula (II), R³ and R⁴ are the same or different and represent a hydrogen atom, a hydrocarbon group having 1 to 4 carbon atoms, or —OM³. In one or more embodiments, at least one of R³ and R⁴ is preferably —OM³, and more preferably —OH from the viewpoint of improving the polishing selectivity and the flatness. In one or more embodiments, at least one of R³ and R⁴ is preferably a hydrogen atom from the viewpoint of improving the polishing selectivity and the flatness.

X represents —SO₃M⁴ or —PO₃M⁵M⁶. In one or more embodiments, X is preferably —SO₃M⁴ from the viewpoint of the dissolution stability.

M³, M⁴, M⁵, and M⁶ are the same or different and represent an alkali metal ion, an alkaline earth metal ion, an organic cation, ammonium (NH₄⁺), or a hydrogen atom. In one or more embodiments, the organic cation may be an organic ammonium, including, e.g., alkylammonium such as tetramethylammonium, tetraethylammonium, and tetrabutylammonium.

In one or more embodiments M³ is preferably at least one selected from an alkali metal ion, ammonium (NH₄⁺), and a hydrogen atom, more preferably at least one selected from a sodium ion, a potassium ion, ammonium (NH₄), and a hydrogen atom, and further preferably a hydrogen atom from the viewpoint of improving the polishing selectivity and the flatness.

In one or more embodiments M⁴, M⁵, and M⁶ are the same or different and preferably represent at least one selected from an alkali metal ion, ammonium (NH₄⁺), and a hydrogen atom, and more preferably represent at least one selected from a sodium ion, a potassium ion, ammonium (NH₄), and a hydrogen atom from the viewpoint of improving the polishing selectivity and the flatness.

In one or more embodiments the constituent monomer b2 is preferably a phenolsulfonic acid (PhS) or a hydroxyphenylphosphonic acid, more preferably a p-phenolsulfonic acid (pPhS) or a (4-hydroxyphenyl)phosphonic acid, and further preferably a p-phenolsulfonic acid (pPhS) from the viewpoint of improving the polishing selectivity.

The molar ratio (%) of the constituent monomer b1 to the total of the constituent monomer b1 and the constituent monomer b2 in the component B is more than 30%, preferably 35% or more, more preferably 40% or more, even more preferably more than 40%, still more preferably 42% or more, yet more preferably 43% or more, further preferably 44% or more, even further preferably 45% or more, still further preferably 46% or more, and yet further preferably 48% or more from the viewpoint of improving the polishing selectivity.

In one or more embodiments the component B is preferably an anionic condensate including a structure represented by the following formula (III) from the viewpoint of improving the polishing selectivity and the flatness.

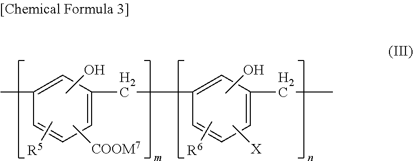

In the formula (III), R⁵ and R⁶ are the same or different and represent a hydrogen atom, a hydrocarbon group having 1 to 4 carbon atoms, or —OM⁸. In one or more embodiments R⁵ and R⁶ preferably represent a hydrogen atom or a hydrocarbon group having 1 to 4 carbon atoms, and more preferably represent a hydrogen atom from the viewpoint of improving the polishing selectivity and the flatness.

M⁷ and M⁸ are the same or different and represent an alkali metal ion, an alkaline earth metal ion, an organic cation, ammonium (NH₄⁺), or a hydrogen atom. In one or more embodiments, the organic cation may be an organic ammonium, including, e.g., alkylammonium such as tetramethylammonium, tetraethylammonium, and tetrabutylammonium.

In one or more embodiments, M⁷ is preferably at least one selected from an alkali metal ion, ammonium (NH₄⁺), and a hydrogen atom, and more preferably at least one selected from a sodium ion, a potassium ion, ammonium (NH₄⁺), and a hydrogen atom from the viewpoint of improving the polishing selectivity and the flatness.

X represents —SO₃M⁹ or —PO₃M¹⁰M¹¹. In one or more embodiments, X is preferably —SO₃M⁹ from the viewpoint of the dissolution stability.

M⁹, M¹⁰, and M¹¹ are the same or different and represent an alkali metal ion, an alkaline earth metal ion, an organic cation, ammonium (NH₄⁺), or a hydrogen atom. In one or more embodiments, the organic cation may be an organic ammonium, including, e.g., alkylammonium such as tetramethylammonium, tetraethylammonium, and tetrabutylammonium.

In the formula (III), m and n represent a mole fraction, provided that m and n satisfym+n=1. In one or more embodiments, m is more than 0.3, preferably 0.35 or more, more preferably 0.4 or more, even more preferably more than 0.4, still more preferably 0.42 or more, yet more preferably 0.43 or more, further preferably 0.44 or more, even further preferably 0.45 or more, still further preferably 0.46 or more, and yet further preferably 0.48 or more from the viewpoint of improving the polishing selectivity. In one or more embodiments, m is 0.8 or less, 0.75 or less, 0.7 or less, or 0.65 or less.

The component B can be produced by polymerization of monomers including, e.g., the constituent monomer b1 and the constituent monomer b2 in the presence of formaldehyde using a known method such as an addition condensation method. In this case, the addition condensation method is preferably used from the viewpoint of improving the hydrolysis resistance and improving the storage stability in an acidic polishing liquid.

In the present disclosure, the content (mol %) of a certain constitutional unit with respect to all the constitutional units of the component B may be defined as the amount (mol %) of the compound that is placed in a reaction vessel to introduce the constitutional unit in question with respect to the total amount of the compounds that are placed in the reaction vessel to introduce all the constitutional units throughout the entire process of synthesis of the component B, depending on the synthesis conditions. In the present disclosure, when the component B contains two or more types of constitutional units the constituent ratio (molar ratio) of two types of constitutional units may be defined as the ratio (molar ratio) of the amounts of the compounds that are placed in the reaction vessel to introduce the two types of constitutional units throughout the entire process of synthesis of the component B, depending on the synthesis conditions.

The component B may further contain additional constitutional units other than the constitutional unit derived from the constituent monomer b1 and the constitutional unit derived from the constituent monomer b2 or the constitutional units in the structure represented by the formula (III).

The arrangement of the constitutional units of the component B can take any form of random, block, or graft.

The weight average molecular weight of the component B is preferably 500 or more, more preferably 1,000 or more, even more preferably 1,500 or more, still more preferably 3,000 or more, yet more preferably 5,000 or more, further preferably 8,000 or more, even further preferably 10,000 or more, still further preferably 15,000 or more, and yet further preferably 20,000 or more from the viewpoint of improving the polishing selectivity and the flatness. From the same viewpoint, the weight average molecular weight of the component B is preferably 1,000,000 or less, more preferably 750,000 or less, even more preferably 500,000 or less, still more preferably 250,000 or less, yet more preferably 100,000 or less, further preferably 75,000 or less, even further preferably 50,000 or less, still further preferably 30,000 or less, and yet further preferably 25,000 or less. Furthermore, from the same viewpoint, the weight average molecular weight of the component B is preferably 500 or more and 1,000,000 or less, more preferably 1,000 or more and 750,000 or less, even more preferably 1,500 or more and 500,000 or less or 1,500 or more and 100,000 or less, still more preferably 3,000 or more and 250,000 or less, yet more preferably 5,000 or more and 100,000 or less, further preferably 8,000 or more and 75,000 or less, even further preferably 10,000 or more and 50,000 or less, still further preferably 15,000 or more and 30,000 or less, and yet further preferably 20,000 or more and 25,000 or less. In the present disclosure, the weight average molecular weight is a value measured by gel permeation chromatography (GPC) under the conditions as described in Examples.

The content of the component B in the polishing liquid composition of the present disclosure is preferably 0.001% by mass or more, more preferably 0.003% by mass or more, even more preferably 0.006% by mass or more, still more preferably 0.01% by mass or more, yet more preferably 0.015% by mass or more, and further preferably 0.02% by mass or more from the viewpoint of improving the polishing selectivity and the flatness. Furthermore, the content of the component B is preferably 10% by mass or less, more preferably 5% by mass or less, even more preferably 1% by mass or less still more preferably 0.5% by mass or less yet more preferably 0.3% by mass or less, and further preferably 0.1% by mass or less from the viewpoint of improving the polishing selectivity. More specifically, the content of the component B is preferably 0.001% by mass or more and 10% by mass or less, more preferably 0.003% by mass or more and 15% by mass or less, even more preferably 0.006% by mass or more and 1% by mass or less, still more preferably 0.006% by mass or more and 0.5% by mass or less, yet more preferably 0.01% by mass or more and 0.5% by mass or less, further preferably 0.015% by mass or more and 0.3% by mass or less, and even further preferably 0.02% by mass or more and 0.1% by mass or less from the viewpoint of improving the polishing selectivity and the flatness.

The mass ratio B/A of the content of the component B to the content of the component A in the polishing liquid composition of the present disclosure is preferably 0.01 or more, more preferably 0.02 or more, even more preferably 0.03 or more, still more preferably 0.04 or more, and further preferably 0.05 or more from the viewpoint of improving the polishing selectivity.

From the same viewpoint, the mass ratio B/A is preferably 0.5 or less, more preferably 0.3 or less, even more preferably 0.15 or less, still more preferably 0.1 or less, and further preferably 0.07 or less. Furthermore, from the same viewpoint, the mass ratio B/A is preferably 0.01 or more and 0.5 or less, more preferably 0.02 or more and 0.3 or less, even more preferably 0.03 or more and 0.15 or less, still more preferably 0.04 or more and 0.1 or less, and further preferably 0.05 or more and 0.07 or less.

[Aqueous Medium]

Examples of the aqueous medium contained in the polishing liquid composition of the present disclosure include water such as distilled water, ion-exchanged water, pure water, and ultrapure water and a mixed solvent of water and a solvent. The solvent may be any solvent that can be mixed with water (e.g., alcohol such as ethanol). When the aqueous medium is a mixed solvent of water and a solvent, the ratio of water to the total mixed medium may be any value that does not impair the effects of the present disclosure, and is preferably, e.g., 95% by mass or more, and more preferably 98% by mass or more in terms of economy. The aqueous medium is preferably water, more preferably ion-exchanged water or ultrapure water, and further preferably ultrapure water in terms of the surface cleanliness of a substrate to be polished. The content of the aqueous medium in the polishing liquid composition of the present disclosure may be the remainder obtained by subtracting the component A, the component B, and optional components that would be added as needed (which will be described later) from the amount of the polishing liquid composition.

[Compound Having Group Represented by Formula (IV) (Component C)]

In one or more embodiments, the polishing liquid composition of the present disclosure may further contain a phosphorus-containing compound having a group represented by the following formula (I)(also referred to simply as a “component C” in the following) from the viewpoint of maintaining the polishing rate and further improving the polishing selectivity. When the polishing liquid composition further contains the component C, the component B is bound to the component C to increase the strength and thickness of the protective film that is to be formed on the polishing stopper film, and thus can further reduce the polishing rate of the polishing stopper film. The component C may be of one type or two or more different types. The component C is preferably water soluble and has a solubility of preferably 0.5 g/100 mL or more in water (at 20° C.).

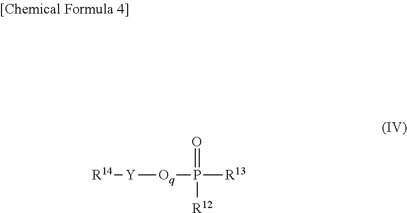

In the formula (V), R¹² and R¹³ are the same or different and represent a hydroxyl group or a salt thereof, R¹⁴ represents H, —NH₂, —NHCH₃, —N(CH₃)₂, —N⁺(CH₃)₃, an alkyl group, a phenyl group, a cytidine group, a guanidino group, or an alkylguanidino group, Y represents a bond or an alkylene group having 1 to 12 carbon atoms, and q represents 0 or 1.

In the formula (V), R¹² and R¹³ are each preferably a hydroxyl group from the viewpoint of improving the solubility in an aqueous medium and improving the stability.

R¹⁴ is preferably H, —NH₂, —N⁺(CH₃)₃, an alkyl group, a phenyl group, a cytidine group, a guanidino group, or an alkylguanidino group, more preferably an alkyl group, a phenyl group, or an alkylguanidino group, and further preferably a phenyl group from the viewpoint of preventing a decrease in the polishing rate of the silicon oxide film. The alkyl group is preferably an alkyl group having 1 to 12 carbon atoms, more preferably an alkyl group having 2 to 6 carbon atoms, and further preferably an alkyl group having 4 carbon atoms (butyl group) from the viewpoint of improving the polishing selectivity and the flatness. The alkylguanidino group is preferably an alkylguanidino group having 2 to 12 carbon atoms, more preferably an alkylguanidino group having 2 to 4 carbon atoms, even more preferably a methylguanidino group, and further preferably a 1-methylguanidino group from the viewpoint of preventing a decrease in the polishing rate of the silicon oxide film and improving the solubility in an aqueous medium.

Y is preferably a bond or an alkylene group having 1 to 12 carbon atoms, more preferably a bond or an alkylene group having 1 to 10 carbon atoms, even more preferably a bond or an alkylene group having 1 to 8 carbon atoms, still more preferably a bond or an alkylene group having 1 to 6 carbon atoms, yet more preferably a bond or an alkylene group having 1 to 4 carbon atoms, further preferably a bond or an alkylene group having 2 or 3 carbon atoms, even further preferably a bond or an alkylene group having 2 carbon atoms (ethylene group), and still further preferably a bond from the viewpoint of improving the solubility in an aqueous medium.

q is preferably 0 from the viewpoint of improving the stability.

Examples of the component C includes the following: a phenylphosphonic acid or a salt thereof a creatinol phosphate or a salt thereof, O-phosphorylethanolamine or a salt thereof a phosphocholine chloride or a salt thereof alkylphosphonic acids (such as a methylphosphonic acid and a butylphosphonic acid) or salts thereof and alkyl phosphates (such as a methyl acid phosphate and a butyl acid phosphate) or salts thereof.

The content of the component C in the polishing liquid composition of the present disclosure is preferably 0.005% by mass or more, more preferably 0.01% by mass or more, even more preferably 0.025% by mass or more, and further preferably 0.05% by mass or more from the viewpoint of improving the polishing selectivity and the flatness. Furthermore, the content of the component C is preferably 0.5% by mass or less, more preferably 0.3% by mass or less, and further preferably 0.15% by mass or less from the viewpoint of improving the polishing rate. More specifically, the content of the component C is preferably 0.005% by mass or more and 0.5% by mass or less, more preferably 0.01% by mass or more and 0.5% by mass or less, even more preferably 0.025% by mass or more and 0.3% by mass or less, and further preferably 0.05% by mass or more and 0.15% by mass or less. When the component C includes two or more types of compounds, the content of the component C is the total content of the two or more types of compounds.

[Other Components]

The polishing liquid composition of the present disclosure may further contain other components such as a pH adjustor, polymers other than the component B, a surfactant, a thickener, a dispersant, a rust preventive, an antiseptic, and a basic substance.

[Polishing Liquid Composition]

The polishing liquid composition of the present disclosure can be produced by a production method that includes blending, e.g., the component A, the component B, and the aqueous medium, and the optional components (the component C and other components) as desired, with a known method. For example, the polishing liquid composition can be produced by blending at least the component A, the component B, and the aqueous medium. In the present disclosure, the term“blend” may include mixing the component A, the component B, and the aqueous medium, and the optional components (the component C and other components) as needed, simultaneously or in sequence. They can be mixed in any order. The blending can be performed, e.g., with a mixer such as a homomixer, a homogenizer, an ultrasonic disperser, or a wet ball mill. The blending amount of each component in the production method of the polishing liquid composition of the present disclosure may be the same as the content of each component in the polishing liquid composition, as described above.

An embodiment of the polishing liquid composition of the present disclosure may be either a so-called one-part or two-part polishing liquid composition. The one-part polishing liquid composition is supplied to the market with all the components being mixed together. On the other hand, the components of the two-part polishing liquid composition are mixed at the time of use. An embodiment of the two-part polishing liquid composition may include a first solution containing the component A and a second solution containing the component B. The first solution and the second solution may be mixed at the time of use. In this case, the first solution and the second solution may be mixed just before application to the surface of an object to be polished. Alternatively, the first solution and the second solution may be supplied separately and mixed on the surface of a substrate to be polished. Each of the first solution and the second solution may contain the above optional components as needed.

From the viewpoint of improving the polishing rate, the pH of the polishing liquid composition of the present disclosure is preferably 3.5 or more, more preferably 4 or more, and further preferably 5 or more. Furthermore, the pH of the polishing liquid composition is preferably 9 or less, more preferably 8.5 or less, and further preferably 8 or less. More specifically, the pH of the polishing liquid composition is preferably 3.5 or more and 9 or less, more preferably 4 or more and 8.5 or less, and further preferably 5 or more and 8 or less. In the present disclosure, the pH of the polishing liquid composition is a value at a temperature of 25° C. and can be measured with a pH meter. Specifically, the pH of the polishing liquid composition can be measured by a method as described in Examples.

The “content of each component in the polishing liquid composition” of the present disclosure means the amount of each component at the time the polishing liquid composition starts to be used for polishing. The polishing liquid composition of the present disclosure may be concentrated so as not to impair the stability, and stored and supplied in the concentrated state. This can reduce the production and transportation costs. If necessary, the concentrated solution may be appropriately diluted with the aqueous medium and used in the polishing process. The dilution factor is preferably 5 to 100.

[Film to be Polished]

The film to be polished with the polishing liquid composition of the present disclosure may be, e.g., a silicon oxide film that is formed in the process of producing a semiconductor substrate. Thus, the polishing liquid composition of the present disclosure can be used in the process that requires polishing of the silicon oxide film. In one or more embodiments the polishing liquid composition of the present disclosure can be suitably used for the following purposes: polishing of a silicon oxide film in the process of forming an element isolation structure of a semiconductor substrate; polishing of a silicon oxide film in the process of forming an interlayer insulation film; polishing of a silicon oxide film in the process of forming embedded metal wiring; or polishing of a silicon oxide film in the process of forming an embedded capacitor. In another one or more embodiment, the polishing liquid composition of the present disclosure can be suitably used for the production of a three-dimensional semiconductor device such as a three-dimensional NAND flash memory.

[Polishing Liquid Kit]

In one aspect, the present disclosure relates to a kit for preparing the polishing liquid composition of the present disclosure (also referred to as a “polishing liquid kit of the present disclosure” in the following).

The polishing liquid kit of the present disclosure may be, e.g., a polishing liquid kit (two-part polishing liquid composition) including an abrasive grain dispersion (first solution) and an additive aqueous solution (second solution) so that they are not mixed with each other. The abrasive grain dispersion contains the component A and the aqueous medium, and the additive aqueous solution contains the component B. The abrasive grain dispersion and the additive aqueous solution are mixed at the time of use, which may be diluted with an aqueous medium as needed. The aqueous medium contained in the abrasive grain dispersion (first solution) may correspond to the whole or part of the amount of the aqueous medium used for the preparation of the polishing liquid composition. The additive aqueous solution (second solution) may contain a part of the aqueous medium used for the preparation of the polishing liquid composition. Each of the abrasive grain dispersion (first solution) and the additive aqueous solution (second solution) may contain the above optional components as needed. In this case, the abrasive grain dispersion (first solution) and the additive aqueous solution (second solution) may be mixed just before application to the surface of an object to be polished. Alternatively, the abrasive grain dispersion and the additive aqueous solution may be supplied separately and mixed on the surface of a substrate to be polished. The polishing liquid kit of the present disclosure can provide the polishing liquid composition capable of improving the polishing rate of the silicon oxide film.

[Polishing Method]

In one aspect, the present disclosure relates to a polishing method that includes polishing a film to be polished with the polishing liquid composition of the present disclosure (also referred to as a “polishing method of the present disclosure” in the following). The film to be polished is a silicon oxide film that is formed in the process of producing a semiconductor substrate. The polishing method of the present disclosure can improve the polishing rate of the silicon oxide film, and thus can be effective in improving the productivity of a high-quality semiconductor substrate. The specific polishing method and conditions may be the same as those of the method for producing a semiconductor substrate of the present disclosure, as described below.

[Method for Producing Semiconductor Substrate]

In one aspect, the present disclosure relates to a method for producing a semiconductor substrate (also referred to as a “production method of a semiconductor substrate of the present disclosure” in the following). The method includes polishing a film to be polished with the polishing liquid composition of the present disclosure (also referred to as a “polishing process using the polishing liquid composition of the present disclosure” in the following). The production method of a semiconductor substrate of the present disclosure may be related to, e.g., a method for producing a semiconductor device, which includes polishing the surface of a silicon oxide film that is opposite to the other surface in contact with a silicon nitride film, e.g., the step height areas of the silicon oxide film with the polishing liquid composition of the present disclosure. The production method of a semiconductor device of the present disclosure enables high-speed polishing of the silicon oxide film, and thus can be effective in efficiently producing a semiconductor device.

The step height areas of the silicon oxide film may be naturally formed according to the raised and trench areas of the underlying layer, on which the silicon oxide film is deposited by, e.g., chemical vapor deposition. Alternatively, the silicon oxide film may be patterned with a series of raised areas and trench areas by, e.g., lithography.

A specific example of the production method of a semiconductor substrate of the present disclosure is as follows. First, a silicon substrate is exposed to oxygen in an oxidation furnace so that a silicon dioxide layer is grown on the surface of the silicon substrate. Then, a polishing stopper film such as a silicon nitride (Si₃N) film or a polysilicon film is formed on the silicon dioxide layer by, e.g., a CVD (chemical vapor deposition) method. Next, trenches are formed by a photolithography technique in a substrate that includes the silicon substrate and the polishing stopper film provided on one of the main surfaces of the silicon substrate, e.g., in a substrate that includes the silicon substrate and the polishing stopper film provided on the silicon dioxide layer of the silicon substrate. Subsequently, a silicon oxide (SiO₂) film (i.e., a film to be polished) is formed to fill the trenches by, e.g., a CVD method using a silane gas and an oxygen gas. Thus, the polishing stopper film is covered with the film to be polished (the silicon oxide film), resulting in a substrate to be polished. Because of the formation of the silicon oxide film, each trench is filled with silicon oxide of the silicon oxide film, and the surface of the polishing stopper film that is opposite to the other surface facing the silicon substrate is covered with the silicon oxide film. Consequently, the surface of the silicon oxide film that is opposite to the other surface facing the silicon substrate has step heights according to the raised and trench areas of the underlying layer. Then, the silicon oxide film is polished by a CMP method until at least the surface of the polishing stopper film that is opposite to the other surface facing the silicon substrate is exposed. More preferably, the silicon oxide film is polished until the surface of the silicon oxide film is flush with the surface of the polishing stopper film. The polishing liquid composition of the present disclosure can be used in this polishing process of the CMP method. The silicon oxide film has raised areas and trench areas according to the raised and trench areas of the underlying layer, and the width of a raised area may be, e.g., 0.5 μm or more and 5000 μm or less and the width of a trench area may be, e.g., 0.5 μm or more and 5000 μm or less.

In the polishing process of the CMP method, the surface of the substrate to be polished is brought into contact with a polishing pad, and the substrate and the polishing pad are moved relative to each other while the polishing liquid composition of the present disclosure is being supplied to the contact area between them, so that the raised and trench areas of the surface of the substrate are planarized.

In the production method of a semiconductor substrate of the present disclosure, another insulation film may be formed between the silicon dioxide layer of the silicon substrate and the polishing stopper film. Alternatively, another insulation film may be formed between the film to be polished (e.g., the silicon oxide film) and the polishing stopper film (e.g., the silicon nitride film or the polysilicon film).

In the polishing process using the polishing liquid composition of the present disclosure, the rotation speed of the polishing pad may be, e.g., 30 to 200 rpm/min, the rotation speed of the substrate to be polished may be, e.g., 30 to 200 rpm/min, the polishing load set in the polishing device including the polishing pad may be, e.g., 20 to 500 g weight/cm², and the supply rate of the polishing liquid composition may be, e.g., 10 to 500 mL/min or less.

Any conventionally known materials may be used for the polishing pad used in the polishing process using the polishing liquid composition of the present disclosure. Examples of the material of the polishing pad include organic polymer foams such as a hard polyurethane foam and non-foams. In particular, the hard polyurethane foam is preferred.

### EXAMPLES

Hereinafter, the present disclosure will be described in detail by way of examples. However, the present disclosure is not limited to the following examples.

1. Preparation of Polishing Liquid Composition

### Examples 1 to 25 and Comparative Examples 1 to 13

Cerium oxide particles (component A): A1 and A2, an anionic condensate (component B): B1 to B6, B11 to B13 or a non-component B: B7 to B10, a phosphorus-containing compound (component C): C1 to C3, and water were mixed to prepare polishing liquid compositions of Examples 1 to 25 and Comparative Examples 1 to 13. Tables 1 to 3 show the content (% by mass) of each component for each polishing liquid composition. The content of water was the remainder obtained by subtracting the component A, the component B or non-component B, and the component C from the amount of the polishing liquid composition. The pH was adjusted by using ammonia or nitric acid.

Cerium oxide particles (component A)

A1: negatively charged ceria (crushed ceria, average primary particle size: 49.5 nm, BET specific surface area: 16.8 m²/g, surface potential: −50 mV)

A2: positively charged ceria (crushed ceria, average primary particle size: 38.3 nm, BET specific surface area: 21.7 m²/g, surface potential 80 mV)

Anionic Condensate (Component B) or Non-Component B

A formaldehyde (co-) condensate was synthesized in the following manner. First, formalin was added dropwise at 85 to 105° C. for 3 to 6 hours so that the amount of formaldehyde was 0.93 to 0.99 mol per 1 mol of the total amount of monomers. After completion of the dropping, a condensation reaction was performed at 95 to 105° C. for 4 to 9 hours. The proportion of the constituent monomers of the copolymer was adjusted by the content (molar ratio) of the monomers.

Visual observation confirmed that the components B1 to B6, B11 to B13 and the non-components B7 to B10 were completely dissolved in their respective polishing liquid compositions.

(Component B)

B1: formaldehyde co-condensate of 4-hydroxybenzoic acid (4-HBA) and p-phenolsulfonic acid (pPhS) (referred to as “HBA/PhS” in the following) (molar ratio of constituent monomers HBA:PhS=50:50), weight average molecular weight: 21000

B2: HBA/PhS (HBA:PhS=50:50), weight average molecular weight: 6900

B3: HBA/PhS (HBA:PhS=50:50), weight average molecular weight: 13500

B4: HBA/PhS (HBA:PhS=50:50), weight average molecular weight: 18000

B5: HBA/PhS(HBA:PhS=55:45), weight average molecular weight: 21000

B6: HBA/PhS(HBA:PhS=60:40), weight average molecular weight: 21000

B11: formaldehyde co-condensate of 2,6-dihydroxybenzoic acid (2,6-HBA) and p-phenolsulfonic acid (pPhS) (referred to as “DHBA/PhS” in the following), DHBA/PhS (DHBA:PhS=50:50), weight average molecular weight: 21000

B12: HBA/PhS (HBA:PhS=40:60), weight average molecular weight: 21000

B13: HBA/PhS (HBA:PhS=35:65), weight average molecular weight: 21000

(Non-Component B)

B7: HBA/PhS(HBA:PhS=20:80), weight average molecular weight: 21000

B8: polyacrylic acid, weight average molecular weight: 24000 (manufactured by Kao Corporation)

B9: formaldehyde co-condensate of naphthalenesulfonic acid, weight average molecular weight: 8000

B10: polystyrene sulfonate, weight average molecular weight: 20000 (manufactured by Tosoh Organic Chemical Co., Ltd.)

Phosphorus-Containing Compound (Component C)

C1: phenylphosphonic acid (manufactured by Tokyo Chemical Industry Co., Ltd.) [In the formula (W), R¹² is OH, R¹³ is OH, R¹⁴ is a phenyl group, Y is a bond, and q is 0.]

C2: creatinol phosphate (manufactured by Tokyo Chemical Industry Co., Ltd.) [In the formula (W), R¹² is OH R¹³ is OH, R¹⁴ is a 1-methylguanidino group, Y is an ethylene group, and q is 1.]

C3: butylphosphonic acid (manufactured by Tokyo Chemical Industry Co., Ltd.) [In the formula (W), R¹² is OH, R¹³ is OH, R¹⁴ is a butyl group, Y is a bond, and q is 0.]

2. Method for Measuring Each Parameter

(1) pH of Polishing Liquid Composition

The pH value of the polishing liquid composition at 25° C. was measured with a pH meter (“HW-41K” manufactured by DKK-TOA CORPORATION). Specifically, the pH value was obtained 1 minute after the electrode of the pH meter was immersed in the polishing liquid composition.

(2) Average Primary Particle Size of Cerium Oxide Particles (Ceria, Component A)

The average primary particle size (nm) of the cerium oxide particles (component A) was calculated using a specific surface area S 2(m²/g) that was determined by the following BET (nitrogen adsorption) method, where the true density of the cerium oxide particles was set to 7.2 g/cm³.

(3) BET Specific Surface Area of Cerium Oxide Particles (Component A)

The specific surface area was measured in the following manner. A dispersion of the cerium oxide particles was dried with hot air at 120° C. for 3 hours, and then finely pulverized in an agate mortar, providing a sample. The sample was dried in an atmosphere at 120° C. for 15 minutes immediately before measuring the specific surface area. Then, the specific surface area was measured by the nitrogen adsorption method (BET method) using a specific surface area measuring device (Micromeritics Automatic Surface Area Analyzer “FlowSorb III 2305” manufactured by Shimadzu Corporation).

(4) Surface Potential of Cerium Oxide Particles (Component A)

The surface potential (mV) of the cerium oxide particles was measured with a surface potential measuring device (“ZetaProbe” manufactured by Kyowa Interface Science Co., Ltd.). The cerium oxide concentration was adjusted to 0.15% using ultrapure water. Then, the solution was introduced into the surface potential measuring device, and the surface potential was measured under the conditions that the particle density was 7.13 g/ml and the particle dielectric constant was 7. The measurement was carried out three times, and the average of the measured values was used as the measurement result.

(5) Weight Average Molecular Weight of Anionic Condensate (Component B and Non-Component B)

The weight average molecular weights of the component B and the non-component B were measured by gel permeation chromatography (GPC) under the following conditions.

<Measurement Conditions>

Column: G4000SWXL+G2000SWXL (manufactured by Tosoh Corporation)

Eluent: 30 mM CH₃COONa/CH₃CN=6/4

Flow rate: 0.7 ml/min

Detection: UV280 nm

Sample size: 0.2 mg/ml

Standard substance: sodium polystyrene sulfonate manufactured by Nishio Industry Co., Ltd. (monodisperse sodium polystyrene sulfonate with a molecular weight of 206, 1800, 4000, 8000, 18000, 35000, 88000, and 780000)

Detector: UV-8020 manufactured by Tosoh Corporation

3. Evaluation of Selection Ratio of Polishing Liquid Composition (Examples 1 to 11, 17 to 25 and Comparative Examples 1 to 6)

(1) Production of Test Piece (Blanket Substrate)

A silicon oxide film (blanket film) with a thickness of 2000 nm was formed on one side of a silicon wafer by a TEOS-plasma CVD method. A square piece of 40 mm×40 mm was cut from the silicon wafer having the silicon oxide film, providing a silicon oxide film test piece (blanket substrate).

Similarly, a silicon nitride film (blanket film) with a thickness of 70 nm was formed on one side of a silicon wafer by a CVD method. A square piece of 40 mm×40 mm was cut from the silicon wafer having the silicon nitride film, providing a silicon nitride film test piece (blanket substrate).

(2) Polishing Rates of Silicon Oxide Film and Silicon Nitride Film

The above test pieces (i.e., the blanket substrates of the silicon oxide film and the silicon nitride film) were polished with each of the polishing liquid compositions of Examples 1 to 11, 17 to 25 and Comparative Examples 1 to 6 under the polishing conditions described below.

<Polishing Conditions>

Polishing device: single-sided polishing machine (TriboLab CMP manufactured by Bruker)

Polishing pad: hard urethane pad (IC-1000/Suba 400 manufactured by Nitta Haas Inc.)

Surface plate rotation speed: 100 rpm

Head rotation speed: 107 rpm

Polishing load: 300 g weight/cm²

Supply of polishing liquid: 50 mL/min

Polishing time: 1 minute

The thickness of the silicon oxide film or the silicon nitride film was measured before and after polishing with an optical interference film thickness measuring device (“VM-1230” manufactured by SCREEN Semiconductor Solutions Co., Ltd.).

The polishing rate of the silicon oxide film (the film to be polished) was calculated by the following formula.

Polishing rate of silicon oxide film (Å/min)=[thickness of silicon oxide film before polishing (Å)−thickness of silicon oxide film after polishing (Å)]/polishing time (min)

The polishing rate of the silicon nitride film (the polishing stopper film) was calculated by the following formula.

Polishing rate of silicon nitride film (Å/min)=[thickness of silicon nitride film before polishing (Å)−thickness of silicon nitride film after polishing (Å)]/polishing time (min)

(3) Polishing Selectivity (Ratio of Polishing Rate)

The ratio of the polishing rate of the silicon oxide film to the polishing rate of the silicon nitride film was calculated by the following formula as a ratio of polishing rate. The larger the ratio of polishing rate, the higher the polishing selectivity.

Ratio of polishing rate=polishing rate of silicon oxide film (min)/polishing rate of silicon nitride film (Å/min)

Table 1 shows the results.

TABLE 1

| | Polishing liquid composition | | | | | | |
|---|---|---|---|---|---|---|---|
| | | | Anionic condensate (component B) | | | | |
| | | | | | Molar | | |
| | Ceria | | | | ratio | | |
| | (component A) | | | Type of | of monomer | | |
| | | Content | | constituent | HBA/PhS or | Molecular | Content |
| | Type | (mass %) | Type | monomer | DHBA/PhS | weight | (mass %) |
| Ex. 1 | A1 | 0.5 | B1 | HBA/PhS | 50/50 | 21000 | 0.025 |
| Ex. 2 | A1 | 0.5 | B1 | HBA/PhS | 50/50 | 21000 | 0.05 |
| Ex. 3 | A1 | 0.5 | B1 | HBA/PhS | 50/50 | 21000 | 0.075 |
| Ex. 4 | A1 | 0.5 | B2 | HBA/PhS | 50/50 | 6900 | 0.025 |
| Ex. 5 | A1 | 0.5 | B3 | HBA/PhS | 50/50 | 13500 | 0.025 |
| Ex. 6 | A1 | 0.5 | B4 | HBA/PhS | 50/50 | 18000 | 0.025 |
| Ex. 7 | A1 | 0.5 | B5 | HBA/PhS | 55/45 | 21000 | 0.025 |
| Ex. 8 | A1 | 0.5 | B6 | HBA/PhS | 60/40 | 21000 | 0.025 |
| Ex. 9 | A2 | 0.5 | B1 | HBA/PhS | 50/50 | 21000 | 0.025 |
| Ex. 10 | A1 | 0.5 | B1 | HBA/PhS | 50/50 | 21000 | 0.025 |
| Ex. 11 | A1 | 0.5 | B1 | HBA/PhS | 50/50 | 21000 | 0.025 |
| Ex. 17 | A1 | 0.5 | B12 | HBA/PhS | 40/60 | 21000 | 0.025 |
| Ex. 18 | A1 | 0.5 | B13 | HBA/PhS | 35/65 | 21000 | 0.025 |
| Ex. 19 | A1 | 0.5 | B11 | DHBA/PhS | 50/50 | 21000 | 0.025 |
| Ex. 20 | A1 | 0.5 | B1 | HBA/PhS | 50/50 | 21000 | 0.025 |
| Ex. 21 | A1 | 0.5 | B1 | HBA/PhS | 50/50 | 21000 | 0.025 |
| Ex. 22 | A1 | 0.5 | B1 | HBA/PhS | 50/50 | 21000 | 0.025 |
| Ex. 23 | A1 | 0.5 | B1 | HBA/PhS | 50/50 | 21000 | 0.025 |
| Ex. 24 | A1 | 0.5 | B1 | HBA/PhS | 50/50 | 21000 | 0.025 |
| Ex. 25 | A1 | 0.5 | B1 | HBA/PhS | 50/50 | 21000 | 0.025 |
| Comp. Ex 1 | A1 | 0.5 | — | — | — | — | — |
| Comp. Ex. 2 | A2 | 0.5 | — | — | — | — | — |
| Comp. Ex. 3 | A1 | 0.5 | B7 | HBA/PhS | 20/80 | 21000 | 0.025 |
| Comp. Ex. 4 | A1 | 0.5 | B8 | polyacrylic acid | — | 24000 | 0.025 |
| Comp. Ex. 5 | A1 | 0.5 | B9 | naphthalenesulfonic | — | 8000 | 0.025 |
| | | | | acid condensate | | | |
| Comp. Ex. 6 | A1 | 0.5 | B10 | polystyrene sulfonate | — | 20000 | 0.025 |

| | Polishing liquid composition | | | | | |
|---|---|---|---|---|---|---|
| | Phosphorus- | | | | | |
| | containing | | | | | Polishing |
| | compound | | | | | selectivity |
| | (component C) | | | Polishing rate | | Ratio of |
| | | Content | pH | SiO₂ film | SiN film | polishing rate |
| | Type | (mass %) | (25° C.) | (Å/min) | (Å/min) | (SiO₂ film/SiN film) |
| Ex. 1 | — | — | 6 | 1063 | 15.6 | 68.14 |
| Ex. 2 | — | — | 6 | 1001.6 | 24.4 | 41.05 |
| Ex. 3 | — | — | 6 | 1057.4 | 18 | 58.74 |
| Ex. 4 | — | — | 6 | 1085 | 18.8 | 57.71 |
| Ex. 5 | — | — | 6 | 1055 | 16.8 | 62.80 |
| Ex. 6 | — | — | 6 | 1035 | 17 | 60.88 |
| Ex. 7 | — | — | 6 | 1009.4 | 16.6 | 60.81 |
| Ex. 8 | — | — | 6 | 1123.8 | 16.2 | 69.37 |
| Ex. 9 | — | — | 6 | 1023.6 | 15.6 | 65.62 |
| Ex. 10 | — | — | 5 | 880.8 | 20.4 | 43.18 |
| Ex. 11 | — | — | 7 | 1074.2 | 25.8 | 41.64 |
| Ex. 17 | — | — | 7 | 1102 | 50.2 | 21.95 |
| Ex. 18 | — | — | 7 | 1082 | 60 | 18.03 |
| Ex. 19 | — | — | 6 | 830 | 13.3 | 62.41 |
| Ex. 20 | C1 | 0.025 | 6 | 876 | 9.1 | 96.27 |
| Ex. 21 | C1 | 0.05 | 6 | 864.5 | 7.5 | 115.65 |
| Ex. 22 | C2 | 0.025 | 6 | 1090.7 | 11.4 | 95.68 |
| Ex. 23 | C2 | 0.05 | 6 | 862.1 | 9.8 | 87.97 |
| Ex. 24 | C3 | 0.025 | 6 | 802.4 | 8.8 | 91.18 |
| Ex. 25 | C3 | 0.05 | 6 | 798.7 | 7.5 | 106.49 |
| Comp. Ex 1 | — | — | 6 | 1521.8 | 486.2 | 3.13 |
| Comp. Ex. 2 | — | — | 6 | 4350.2 | 724.6 | 6.00 |
| Comp. Ex. 3 | — | — | 6 | 1078.8 | 126.2 | 8.55 |
| Comp. Ex. 4 | — | — | 6 | 1067.8 | 79.2 | 13.48 |
| Comp. Ex. 5 | — | — | 6 | 1125.8 | 281.6 | 4.00 |
| Comp. Ex. 6 | — | — | 6 | 1049.8 | 342.6 | 3.06 |

As shown in Table 1, the polishing liquid compositions of Examples 1 to 11, 17 to 19 significantly reduced the polishing rate of the silicon nitride film without significantly impairing the polishing rate of the silicon oxide film, and thus improved the polishing selectivity, as compared to the polishing liquid compositions of Comparative Examples 1 and 6, each of which did not contain the component B. The polishing liquid compositions of Examples 20 to 25, each of which further contained the component C, further significantly reduced the polishing rate of the silicon nitride film without significantly impairing the polishing rate of the silicon oxide film, and thus further improved the polishing selectivity, as compared to the polishing liquid composition of Example 1, which did not contain the component C.

4. Evaluation of Dishing of Polishing Liquid Composition (Examples 12 to 13 and Comparative Examples 7 to 10)

The polishing rate of the silicon nitride film and the dishing rate during overpolishing were evaluated by using each of the polishing liquid compositions of Examples 12 to 13 and Comparative Examples 7 to 10. The evaluation method is as follows.

(1) Test Piece (Patterned Substrate)

A commercially available wafer for evaluating CMP characteristics (“P-TEOS MIT 864 PT wafer” manufactured by ADVANTEC, diameter: 300 mm) was used as a patterned substrate for evaluation. This patterned substrate had been etched to make a linear pattern of raised areas and trench areas. Each raised area was formed of a silicon nitride film (first layer) with a thickness of 150 nm and a silicon oxide film (second layer) with a thickness of 450 nm. Similarly, the silicon oxide film with a thickness of 450 nm was disposed in each trench area. A step height between the raised area and the trench area was 350 nm. The silicon oxide film was composed of P-TEOS. The raised areas and the trench areas each having a line width of 100 μm, were used as measuring objects.

(2) Polishing

The blanket substrates (corresponding to the silicon oxide film and the silicon nitride film) of the above item 3. (1) and the patterned substrate of the above item (1) were polished with each of the polishing liquid compositions of Examples 12 to 13 and Comparative Examples 7 to 10 under the polishing conditions described below.

<Polishing Conditions>

Polishing device: single-sided polishing machine (F REX-300 manufactured by EBARA CORPORATION)

Polishing pad: hard urethane pad (IC-1000/Suba 400 manufactured by Nitta Haas Inc.)

Surface plate rotation speed: 100 rpm

Head rotation speed: 107 rpm

Polishing load: 300 g weight/cm²

Supply of polishing liquid: 200 mL/min

Polishing time: 1 minute (for each of the silicon oxide film substrate and the silicon nitride film substrate), planarization time+overpolishing time (for the patterned substrate)

(3) Polishing Selectivity

The polishing rate and the polishing selectivity were calculated by using the blanket substrates in the same manner as described in the above items 3. (2) and (3).

(4) Planarization Time

The time (sec) required for planarization of the protruding silicon oxide film of the test piece (patterned substrate) was measured and defined as a planarization time.

(5) Polishing Rate of Silicon Nitride Film During Overpolishing

After the silicon nitride film was exposed due to the planarization of the protruding silicon oxide film, the patterned substrate was excessively polished for a period of time that was 20% of the time it took to planarize the protruding silicon oxide film (i.e., the planarization time). The thickness of the silicon nitride film was measured before and after excessive polishing with Spectra FX200 (manufactured by KLA Corporation). The polishing rate of the silicon nitride film during overpolishing was calculated by the following formula.

Polishing rate of silicon nitride film after exposure of silicon nitride film (Å/sec)=[thickness of silicon nitride film at the start of exposure of silicon nitride film (Å)−thickness of silicon nitride film at the end of polishing (Å)]/overpolishing time (sec)

(6) Dishing Rate During Overpolishing

After the silicon nitride film was exposed due to the planarization of the protruding silicon oxide film, the patterned substrate was excessively polished for a period of time that was 20% of the time it took to planarize the protruding silicon oxide film (i.e., the planarization time). The thickness of the silicon oxide film disposed in a trench area was measured before and after excessive polishing with Spectra FX200 (manufactured by KLA Corporation). The dishing rate during overpolishing was calculated by the following formula.

Polishing rate of silicon oxide film in trench area after exposure of silicon nitride film (Å/sec)=[thickness of silion oxide film in trench area at the start of exposure of silicon nitride film (Å)−thickness of silicon oxide film in trench area at the end of polishing (Å)]/overpolishing time (sec)

Table 2 shows the results.

TABLE 2

| | Polishing liquid composition | | | | | | | | | |
|---|---|---|---|---|---|---|---|---|---|---|
| | | | | | | | | Phosphorus- | | |
| | | | | | | | | containing | | |
| | Ceria | | Anionic condensate (component B) | | | | | compound | | |
| | (component A) | | | Type of | Molar ratio | | | (component C) | | |
| | | Content | | constituent | of monomer | Molecular | Content | | Content | pH |
| | Type | (mass %) | Type | monomer | HBA/PhS | weight | (mass %) | Type | (mass %) | (25° C.) |
| Ex. 12 | A1 | 0.5 | B1 | HBA/PhS | 50/50 | 21000 | 0.025 | — | | 6 |
| Ex. 13 | A1 | 0.5 | B1 | HBA/PhS | 50/50 | 21000 | 0.025 | C1 | 0.05 | 6 |
| Comp. Ex. 7 | A1 | 0.5 | — | — | — | — | — | — | — | 6 |
| Comp. Ex. 8 | A1 | 0.5 | B7 | HBA/PhS | 20/80 | 21000 | 0.025 | — | — | 6 |
| Comp. Ex. 9 | A1 | 0.5 | B8 | polyacrylic acid | — | 24000 | 0.025 | — | — | 6 |
| Comp. Ex. 10 | A1 | 0.5 | B9 | naphthalenesulfonic | — | 8000 | 0.025 | — | — | 6 |
| | | | | acid condensate | | | | | | |

| | Blanket substrate | | | Patterned substrate | | |
|---|---|---|---|---|---|---|
| | | | | | Overpolishing | |
| | | | Polishing selectivity | | Polishing | |
| | Polishing rate | | Ratio of | Planarization | rate of | Dishing |
| | SiO₂ film | SiN film | polishing rate | time | SiN film | rate |
| | (Å/min) | (Å/min) | (SiO₂ film/SiN film) | (sec) | (Å/sec) | (Å/sec) |
| Ex. 12 | 2326 | 40 | 58.15 | 120 | 1.98 | 3.24 |
| Ex. 13 | 2065 | 23 | 89.78 | 105 | 1.74 | 1.07 |
| Comp. Ex. 7 | 3269 | 533 | 6.13 | 110 | 17.15 | 16.83 |
| Comp. Ex. 8 | 2390 | 70 | 34.14 | 150 | 6.50 | 8.20 |
| Comp. Ex. 9 | 2285 | 66 | 34.62 | 150 | 3.30 | 7.23 |
| Comp. Ex. 10 | 2355 | 59 | 39.92 | 140 | 5.51 | 7.16 |

As shown in Table 2, the polishing liquid compositions of Examples 12 to 13 improved the polishing selectivity while maintaining the polishing rate of the silicon oxide film, as compared to the polishing liquid compositions of Comparative Example 7 to 10, each of which did not contain the component B. Moreover, the polishing liquid compositions of Examples 12 to 13 were found to reduce the polishing rate of the silicon nitride film and the dishing rate during overpolishing, as compared to the polishing liquid compositions of Comparative Examples 7 to 10. The polishing liquid composition of Example 13, which further contained the component C, further improved the polishing selectivity and further reduced the polishing rate of the silicon nitride film and the dishing rate during overpolishing, as compared to the polishing liquid composition of Example 12, which did not contain the component C.

5. Evaluation of Polishing Liquid Composition (Examples 14 to 16 and Comparative Examples 11 to 13)

(1) Production of Test Piece

A silicon oxide film with a thickness of 2000 nm was formed on one side of a silicon wafer by a TEOS plasma CVD method. A square piece of 40 mm×40 mm was cut from the silicon wafer having the silicon oxide film, providing a silicon oxide film test piece. Similarly, first, a thermal oxidation film with a thickness of 100 nm was formed on one side of a silicon wafer, and then a polysilicon film with a thickness of 500 nm was formed by a CVD method. A square piece of 40 mm×40 mm was cut from the silicon wafer having the thermal oxidation film and the polysilicon film, providing a polysilicon film test piece.

(2) Measurement of Polishing Rate of Silicon Oxide Film

The polishing rate of the silicon oxide film was calculated by using each of the polishing liquid compositions of Examples 14 to 16 and Comparative Examples 11 to 13 in the same manner as the measurement of the polishing rates of the silicon oxide film and the silicon nitride film, which used the polishing liquid compositions of Examples 1 to 11 and Comparative Examples 1 to 6, as described above.

(3) Measurement of Polishing Rate of Polysilicon Film

The polysilicon film was polished, the thickness of the polysilicon film was measured, and the polishing rate of the polysilicon film was calculated in the same manner as the measurement of the polishing rate of the silicon oxide film, as described above, except that the polysilicon film test piece was used instead of the silicon oxide film test piece.

(4) Polishing Selectivity (Ratio of Polishing Rate)

The ratio of the polishing rate of the silicon oxide film to the polishing rate of the polysilicon film (SiO₂ film/poly-Si film) was calculated by the following formula as a ratio of polishing rate. The larger the ratio of polishing rate, the better the polishing selectivity. Such polishing liquid compositions have a high ability to eliminate step heights.

Ratio of polishing rate=polishing rate of silicon oxide film(Å/min)/polishing rate of polysilicon film (Å/min)

Table 3 shows the results.

TABLE 3

| | Polishing liquid composition | | | | | | | | | | Polishing |
|---|---|---|---|---|---|---|---|---|---|---|---|
| | | | Anionic condensate (component B) | | | | | | | | selectivity |
| | | | | | Molar | | | | | | Ratio of |
| | Ceria | | | | ratio of | | | | Polishing rate | | polishing rate |
| | (component A) | | | Type of | monomer | | | | SiO₂ | poly-Si | (SiO₂ film/ |
| | | Content | | constituent | HBA/PhS or | Molecular | Content | pH | film | film | poly-SiN |
| | Type | (mass %) | Type | monomer | DHBA/PhS | weight | (mass %) | (25° C.) | (Å/min) | (Å/min) | film) |
| Ex. 14 | A1 | 0.5 | B1 | HBA/PhS | 50/50 | 21000 | 0.025 | 6 | 2970 | 200 | 14.85 |
| Ex. 15 | A1 | 0.5 | B1 | HBA/PhS | 50/50 | 21000 | 0.05 | 6 | 2945 | 190 | 15.50 |
| Ex. 16 | A1 | 0.5 | B11 | DHBA/PhS | 50/50 | 21000 | 0.025 | 6 | 2080 | 130 | 16.00 |
| Comp. Ex. 11 | A1 | 0.5 | — | — | — | — | — | 6 | 4241 | 630 | 6.73 |
| Comp. Ex. 12 | A1 | 0.5 | B9 | naphthalenesulfonic | — | 8000 | 0.025 | 6 | 3149 | 450 | 7.00 |
| | | | | acid condensate | | | | | | | |
| Comp. Ex. 13 | A1 | 0.5 | B8 | polyacrylic acid | — | 24000 | 0.025 | 6 | 2664 | 350 | 7.61 |

As shown in Table 3, the polishing liquid compositions of Examples 14 to 16 significantly reduced the polishing rate of the polysilicon film without significantly impairing the polishing rate of the silicon oxide film, and thus improved the polishing selectivity, as compared to the polishing liquid compositions of Comparative Examples 11 to 13, each of which did not contain the component B.

### INDUSTRIAL APPLICABILITY

In one or more embodiments, the polishing liquid composition of the present disclosure is useful in a method for producing a semiconductor substrate for high density or high integration.

1. A polishing liquid composition for a silicon oxide film comprising:
cerium oxide particles (component A);
a water-soluble anionic condensate (component B); and
an aqueous medium,
wherein the component B is a co-condensate of monomers including a monomer (constituent monomer b1) represented by the following formula (I) and a monomer (constituent monomer b2) represented by the following formula (II), and
a molar ratio (%) of the constituent monomer b1 to the total of the constituent monomer b1 and the constituent monomer b2 in the component B is more than 30%: 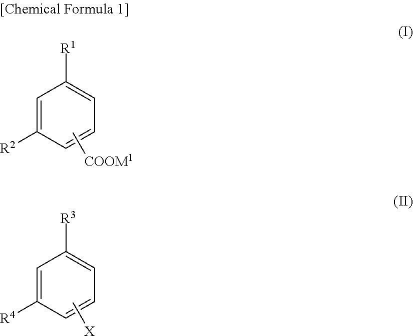
in the formula (I), R¹ and R² are the same or different and represent a hydrogen atom, a hydrocarbon group having 1 to 4 carbon atoms, or —OM², and M¹ and M² are the same or different and represent an alkali metal ion, an alkaline earth metal ion, an organic cation, ammonium (NH₄⁺), or a hydrogen atom,
in the formula (II), R³ and R⁴ are the same or different and represent a hydrogen atom, a hydrocarbon group having 1 to 4 carbon atoms, or —OM³, X represents —SO₃M⁴ or —PO₃M⁵M⁶, and M³, M⁴, M⁵, and M⁶ are the same or different and represent an alkali metal ion, an alkaline earth metal ion, an organic cation, ammonium (NH₄⁺), or a hydrogen atom.

2. The polishing liquid composition according to claim 1, wherein the component B is an anionic condensate including a structure represented by the following formula (III): 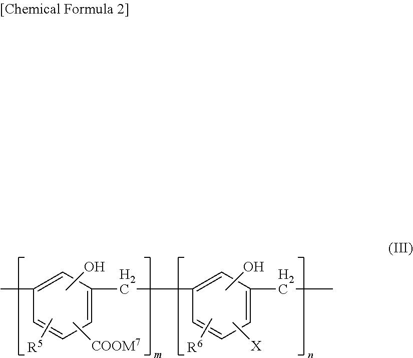
in the formula (III), R⁵ and R⁶ are the same or different and represent a hydrogen atom, a hydrocarbon group having 1 to 4 carbon atoms, or —OM⁸, X represents —SO₃M⁹ or —PO₃M¹⁰M¹¹, M⁷, M⁸, M⁹, M¹⁰, and M¹¹ are the same or different and represent an alkali metal ion, an alkaline earth metal ion, an organic cation, ammonium (NH₄⁺), or a hydrogen atom, and m and n represent a mole fraction, provided that m and n satisfy m+n=1, and m is more than 0.3.

3. The polishing liquid composition according to claim 2, wherein m in the formula (III) is 0.45 or more.

4. The polishing liquid composition according to claim 1, wherein a weight average molecular weight of the component B is 1,500 or more and 100,000 or less.

5. The polishing liquid composition according to claim 1, wherein a content of the component B in the polishing liquid composition is 0.006% by mass or more and 0.5% by mass or less.

6. The polishing liquid composition according to claim 1, wherein a content of the component A in the polishing liquid composition is 0.001% by mass or more and 6% by mass or less.

7. The polishing liquid composition according to claim 1, further comprising a phosphorus-containing compound (component C) represented by the following formula (IV): 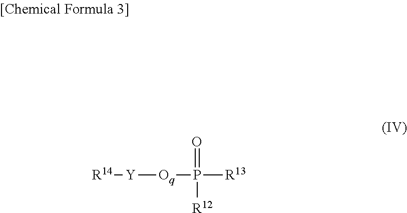
in the formula (IV), R¹² and R¹³ are the same or different and represent a hydroxyl group or a salt thereof, R¹⁴ represents H, —NH₂, —NHCH₃, —N(CH₃)₂, —N⁺(CH₃)₃, an alkyl group, a phenyl group, a cytidine group, a guanidino group, or an alkylguanidino group, Y represents a bond or an alkylene group having 1 to 12 carbon atoms, and q represents 0 or 1.

8. The polishing liquid composition according to claim 7, wherein the component C is a phenylphosphonic acid or a salt thereof.

9. The polishing liquid composition according to claim 7, wherein a content of the component C is 0.005% by mass or more and 0.5% by mass or less.

10. A method for producing a semiconductor substrate, comprising:
polishing a film to be polished with the polishing liquid composition according to claim 1.

11. A polishing method comprising:
polishing a film to be polished with the polishing liquid composition according to claim 1,
wherein the film to be polished is a silicon oxide film that is formed in a process of producing a semiconductor substrate.
